(19) United States
(12) Patent Application Publication
(10) Pub. No.: US 2025/0374614 A1
(43) Pub. Date: Dec. 4, 2025

(54) SEMICONDUCTOR DEVICE AND METHOD

(71) Applicant: Taiwan Semiconductor Manufacturing Co., Ltd., Hsinchu (TW)

(72) Inventors: Yu-Lin Tsai, Hsinchu (TW); Kuan-Ting Lee, Hsinchu City (TW); Hua-Yun Lee, Kaohsiung City (TW); Ya-Wei Liao, Hsinchu (TW); Li-Chao Yin, Hsinchu (TW); Hsiu-Hao Tsao, Taichung (TW); An Chyi Wei, Hsinchu (TW); Ryan Chia-Jen Chen, Hsinchu (TW)

(21) Appl. No.: 18/827,259

(22) Filed: Sep. 6, 2024

Related U.S. Application Data
(60) Provisional application No. 63/655,188, filed on Jun. 3, 2024.

(51) Int. Cl. H01L 29/78; H01L 21/02; H01L 29/06; H01L 29/423; H01L 29/66; H01L 29/775; H01L 29/786

(52) U.S. Cl. CPC H10D 30/797; H01L 21/02532; H10D 30/014; H10D 30/43; H10D 30/6735; H10D 30/6757; H10D 62/121; H10D 64/017; H10D 64/018

(57) ABSTRACT

In an embodiment, a method may include forming a multi-layer stack over a substrate, the multi-layer stack having alternating layers of first semiconductor layers and second semiconductor layers. The method may also include removing the first semiconductor layers. Furthermore, the method may include forming a disposable material between the second semiconductor layers. In addition, the method may include forming source/drain regions adjacent to the second semiconductor layers and the disposable material. Moreover, the method may include replacing the disposable material with a metal gate structure, where a germanium concentration in the second semiconductor layers after replacing the disposable material with the metal gate structure is in a range from 10⁻² to 10⁻³ percent.

### PRIORITY CLAIM AND CROSS-REFERENCE

This application claims the benefit of U.S. Provisional Application No. 63/655,188 filed on Jun. 3, 2024, entitled “Nanosheet Device Performance Boost by DOI Process,” which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 10A, 10B, 10C, 10D, 10E, 11A, 11B, 11C, 11D, 11E, 12A, 12B, 13A, 13B, 14A, 14B, 15A, 15B, 15C, 15D, 16A, 16B, 16C, 17A, 17B, 17C, 18A, 18B, and 18C illustrate varying views of intermediary steps of manufacturing a nano-FET transistor, in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to semiconductor device manufacturing, specifically to a method for nanostructure field-effect transistor (nano-FET) formation using a disposable oxide interposer (DOI) scheme. As the semiconductor industry continues to pursue device scaling and performance improvements, managing impurities and structural precision in nanoscale devices has become increasingly important. The DOI process introduced in this disclosure is particularly beneficial in addressing the issue of germanium (Ge) impurity residue in nano-FET devices, which has been identified as a factor that can negatively impact device performance.

The process may begin with the formation of a first fin structure comprising alternating sacrificial layers and semiconductor layers. In a step that distinguishes this process from related methods, the sacrificial layers are replaced with a plurality of oxide layers. These oxide layers serve as disposable interposers, allowing for precise control of the device structure. Subsequently, a portion of these oxide layers is removed to form inner spacer recesses, and inner spacers are formed in these recesses. The remaining portion of the oxide layers is then removed, and a gate stack is formed to wrap around each of the semiconductor layers, completing the basic nano-FET structure.

The DOI process results in several potential benefits that address challenges in advanced node semiconductor manufacturing. One advantage is the full removal of silicon-germanium (SiGe) at an earlier stage of the process. This early removal significantly mitigates the diffusion of Ge through source/drain (SD) regions and interlayer dielectric (ILD) during subsequent thermal steps. Consequently, the process results in substantially lower Ge concentration in the final device structure, typically in the range of 10⁻² to 10⁻³ percent (e.g., less than 0.003%). This reduction in Ge impurity can favorably alter the stress profile in NFET and PFET devices, potentially enhancing electron and hole mobility, respectively. These improvements in carrier mobility can lead to a notable boost in overall device performance.

The structural characteristics of devices produced by the DOI process can vary depending on the specific implementation, offering flexibility in device design. In some embodiments, the DOI process may result in thinner nanostructure channels (often silicon channel nanostructures), which can improve electrostatic control in the channel region. The process also typically yields devices with substantially no SiGe residue, enhancing the purity of the channel material. Inner spacers produced by this method can be either squared (flat) or rounded, and are often thicker than those in related processes, providing better isolation between the gate and source/drain regions. The gate structure itself may be larger, potentially reducing gate resistance. Additionally, the interface between the inner spacer and the gate structure can be engineered to be either squared or rounded, offering another parameter for device optimization.

The present disclosure provides several embodiments of the method, each with potential variations in the inner spacer geometry and the thickness of the nanostructures. These embodiments illustrate the versatility of the DOI process in producing a range of nano-FET structures tailored to specific performance requirements. While these embodiments are illustrative of the process capabilities, they are not intended to limit the scope of the disclosure.

Embodiments are described below in a particular context, a die comprising nano-FETs. Various embodiments may be applied, however, to dies comprising other types of transistors (e.g., stacking transistors, or the like) in lieu of or in combination with the nano-FETs.

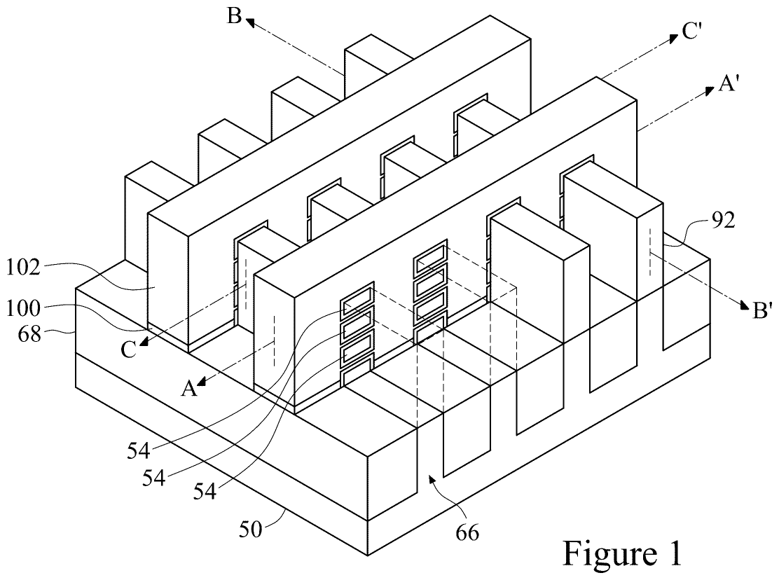

FIG. 1 illustrates an example of nano-FETs (e.g., nanowire FETs, nanosheet FETs (nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the second nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

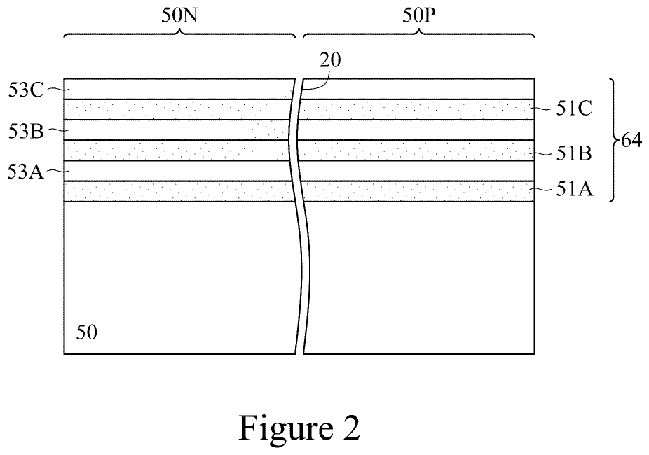

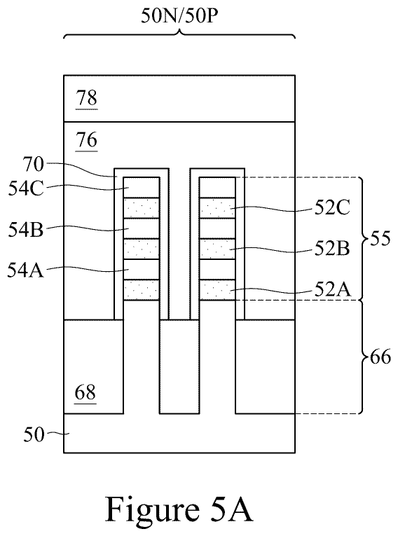

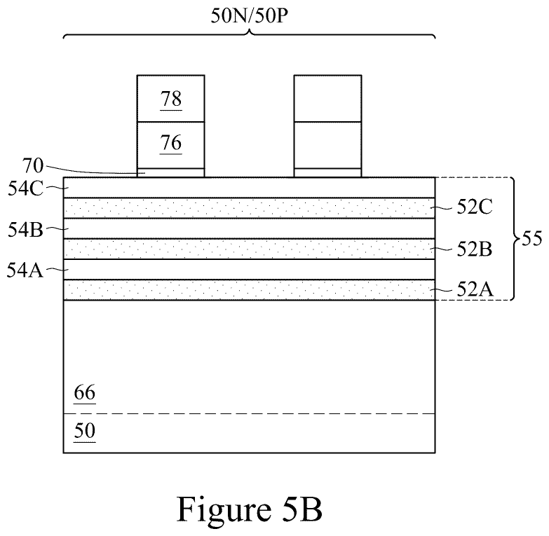

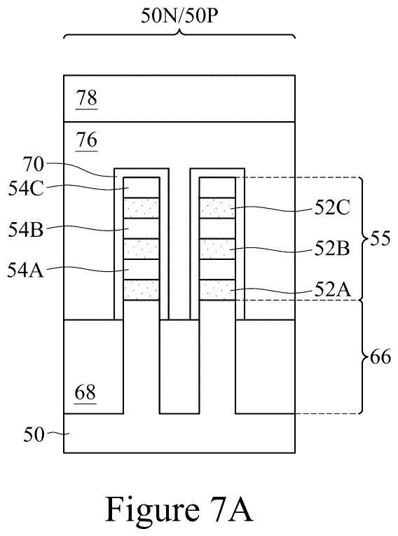

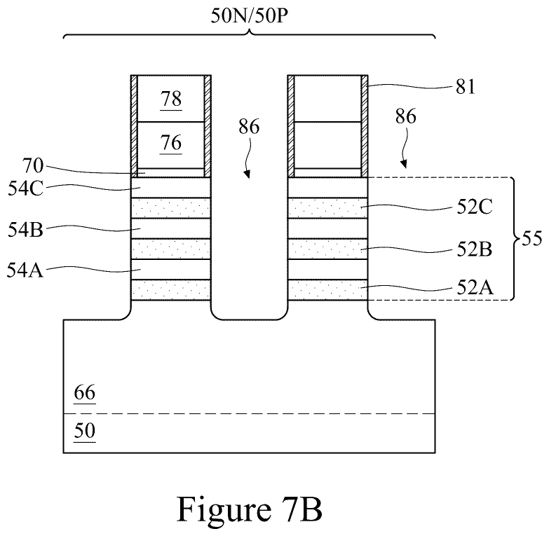

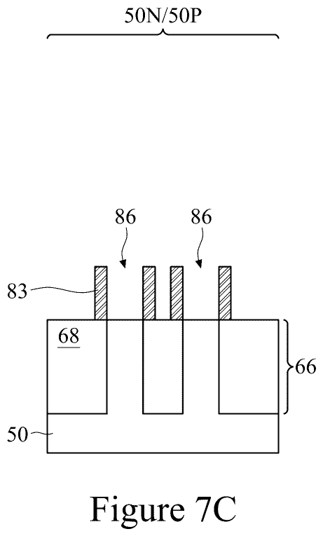

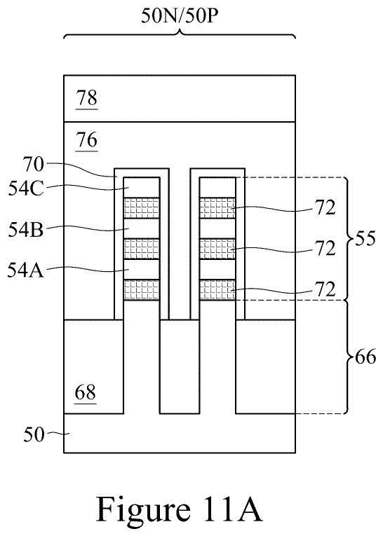

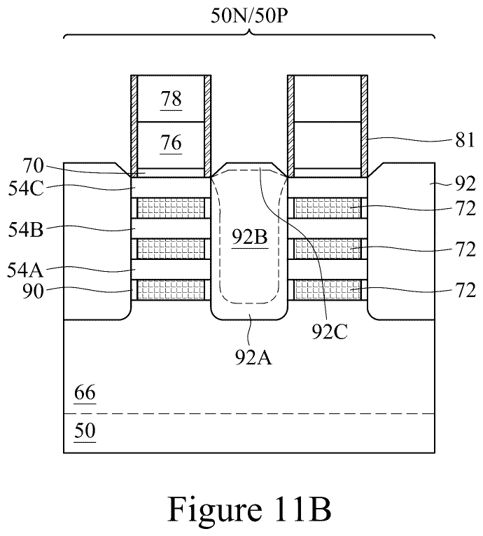

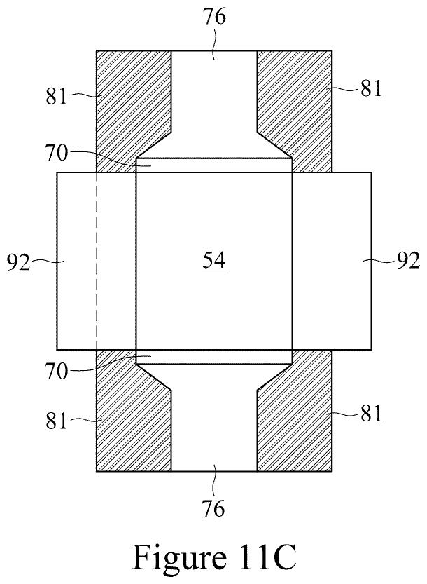

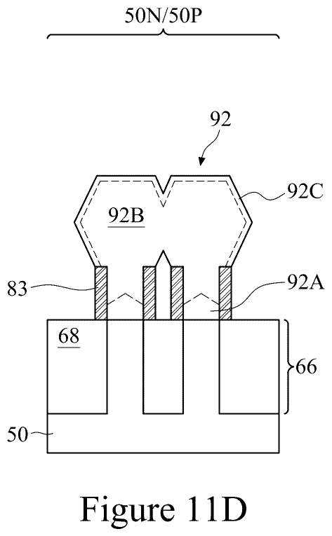

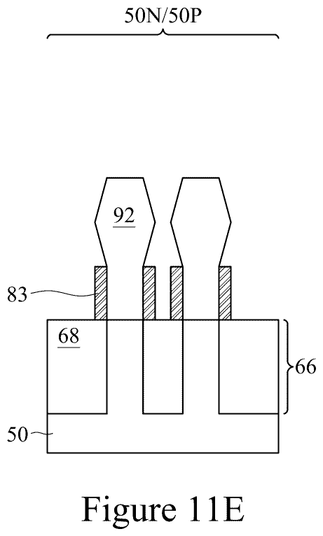

FIGS. 2 through 19C are cross-sectional views of intermediate stages in the manufacturing of nano-FETs, in accordance with some embodiments. FIGS. 2,3, 4, 5A, 6A, 7A, 8A, 9A, 10A, 11A, 12A, 13A, 14A, 15A, 16A, 17A, and 18A, illustrate reference cross-section A-A′ illustrated in FIG. 1. FIGS. 5B, 6B, 7B, 8B, 9B, 10B, 10C, 10D, 10E, 11B, 12B, 13B, 14B, 15B, 15C, 15D, 16B, 17B, and 18B illustrate reference cross-section B-B′ illustrated in FIG. 1. FIGS. 7C, 11D, 11E, 16C, 17C, and 18C illustrate reference cross-section C-C′ illustrated in FIG. 1. FIG. 11C illustrates a plan view of intermediate stage in the manufacturing of nano-FETs, in accordance with some embodiments.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

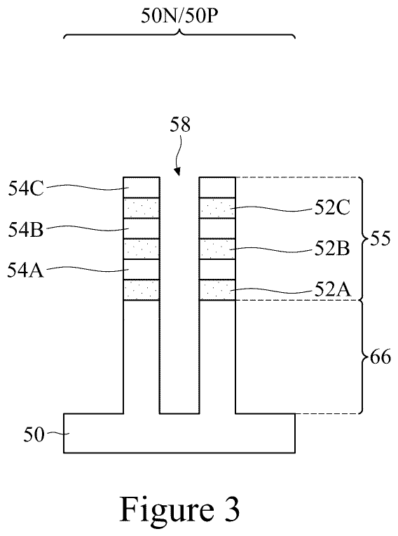

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

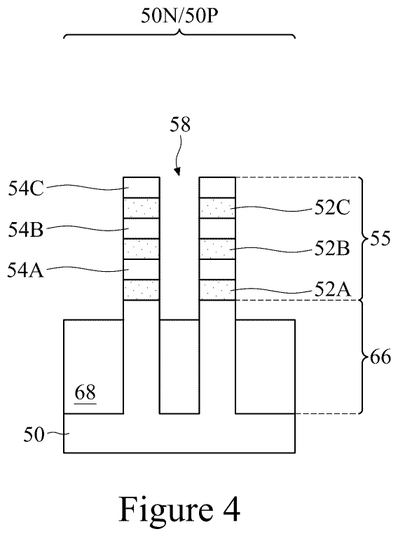

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

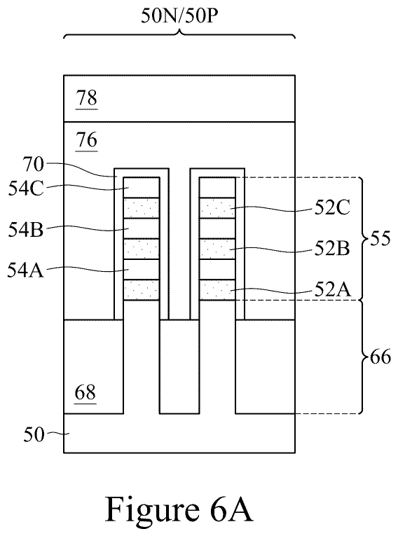

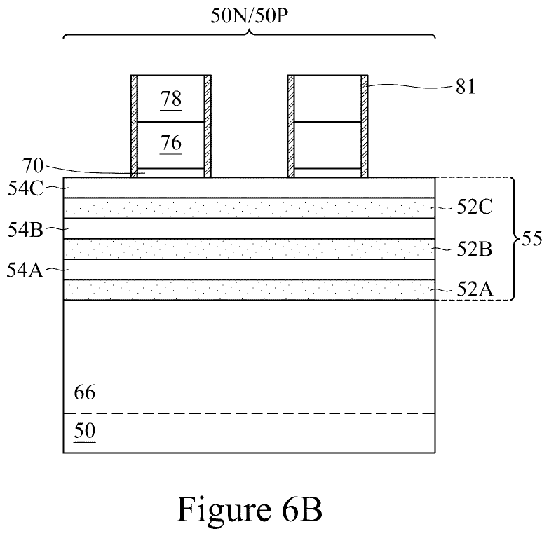

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

Itis noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

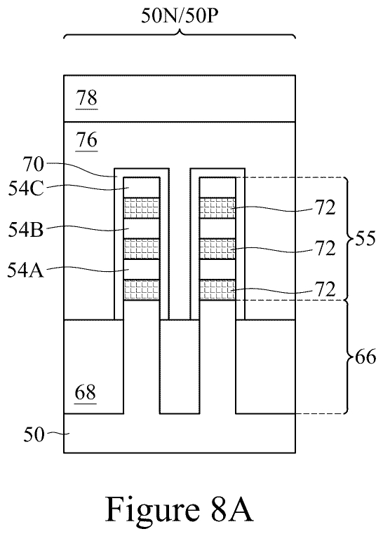

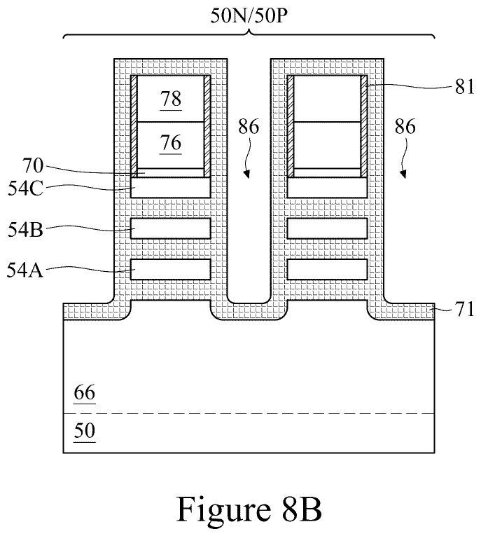

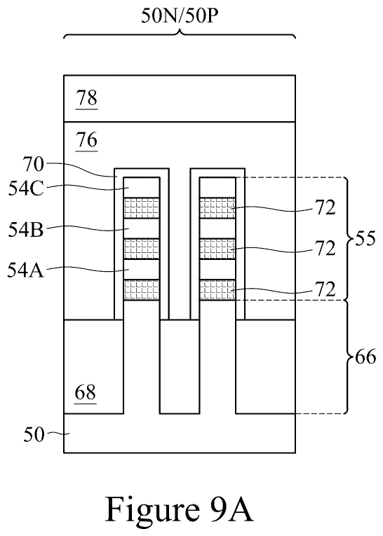

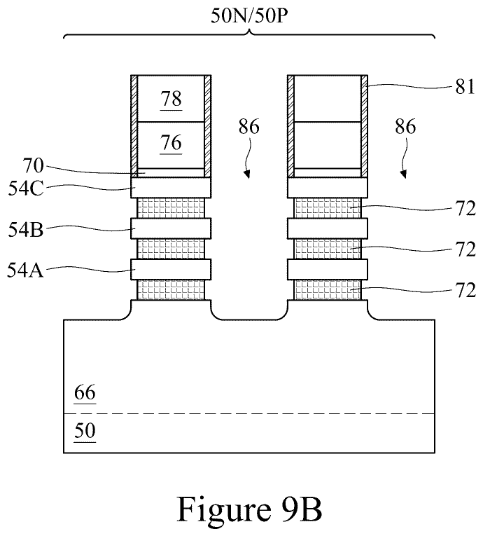

In FIGS. 8A-9B, the first nanostructures 52 are replaced with with a sacrificial material 72 (also referred to as disposable interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer 71 may comprise an insulating material such as silicon oxide (e.g., SiO₂), silicon oxynitride, silicon nitride, silicon oxycarbonitride, hafnium oxide, aluminum oxide, or the like that can be selectively etched from the second nanostructures 54. In some embodiments, the sacrificial material layer 71 may comprise a photoresist material or the like.

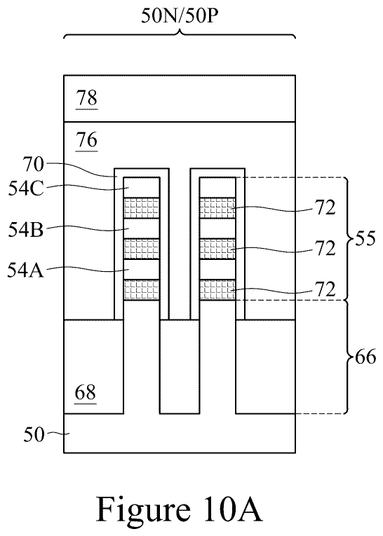

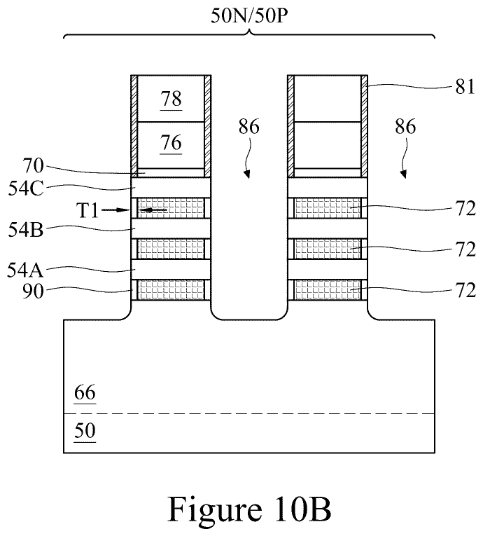

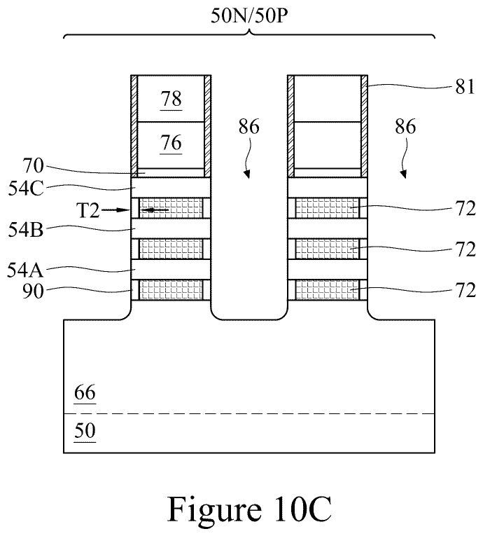

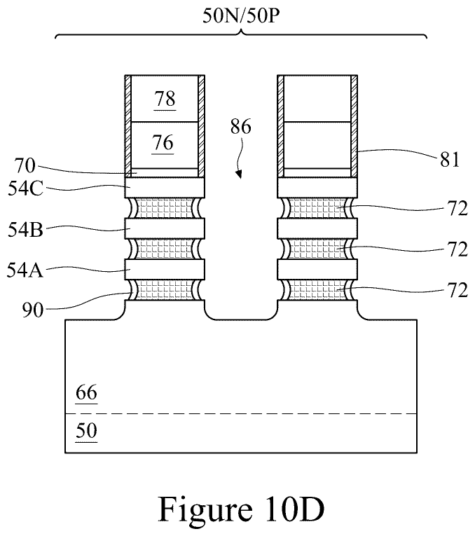

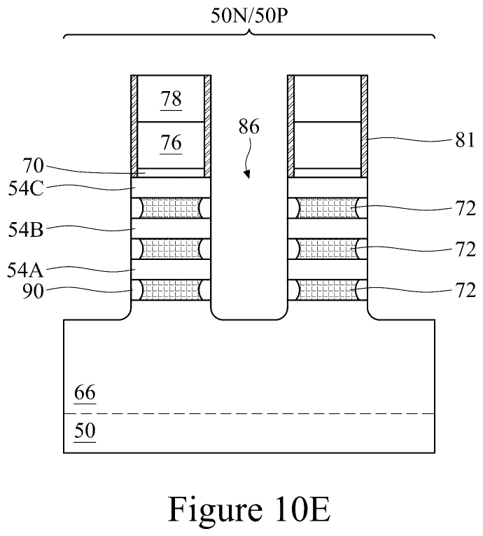

In FIGS. 9A-9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the second nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high-temperature processes (e.g., source/drain annealing), manufacturing defects can be reduced, and device performance can be improved (e.g., increased current drive, reduced capacitance, and improved short channel effect).

In FIGS. 10A and 10B, inner spacers 90 are formed in the first recesses 86 on the sidewalls of the sacrificial material 72. The inner spacers 90 act as isolation features between subsequently formed source/drain regions and a gate structure. As will be discussed in greater detail below, source/drain regions will be formed in the first recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 10A and 10B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

In FIG. 10B, the inner and outer sidewalls of the inner spacers 90 are illustrated as being flat with a thickness T1. Further in FIG. 10B, the outer sidewalls of the inner spacers 90 are illustrated as being flush with sidewalls of the second nanostructures 54, but the outer sidewalls of the inner spacers 90 may extend beyond or be recessed from sidewalls of the second nanostructures 54 (see e.g., FIG. 10D).

FIG. 10C illustrates an embodiment similar to FIG. 10B with the inner and outer sidewalls of the inner spacers 90 being flat, but in FIG. 10C, the inner spacers 90 have a thickness T2 which is larger than T1. This flat shape of the inner spacers 90 contrasts with the rounded shape described in some embodiments, providing different options for optimizing the device structure. The flat shape may offer advantages in terms of more precise control over the spacing between the channel regions and the source/drain regions, while the rounded shape may provide benefits in terms of stress distribution or manufacturing simplicity.

In some embodiments, the outer sidewalls of the inner spacers 90 may be concave or convex. As an example, FIG. 10D illustrates an embodiment in which sidewalls of the sacrificial material 72 are concave, outer sidewalls of the inner spacers 90 are concave, and the inner spacers 90 are recessed from sidewalls of the second nanostructures 54. In another embodiment, the inner spacers 90 of FIG. 10D may be formed to a larger thickness and not be recessed from sidewalls of the second nanostructures 54.

FIG. 10E illustrates an embodiment in which sidewalls of the sacrificial material 72 are concave and the outer sidewalls of the inner spacers 90 are flat. Further, in some embodiments the outer sidewalls of the inner spacers 90 are flush with sidewalls of the second nanostructures 54.

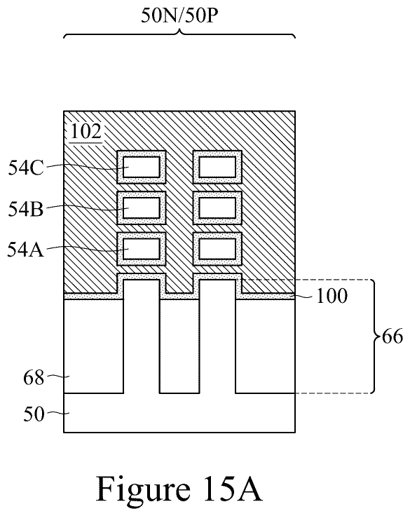

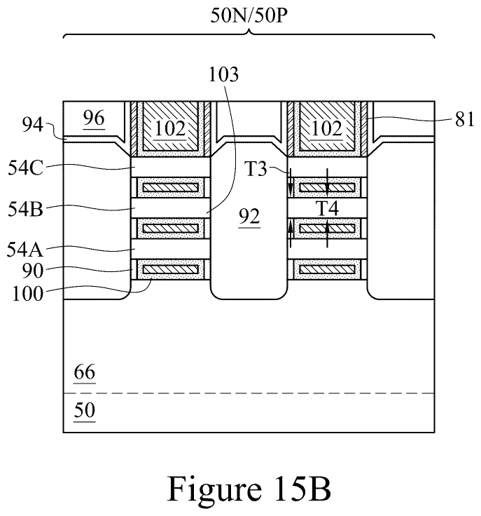

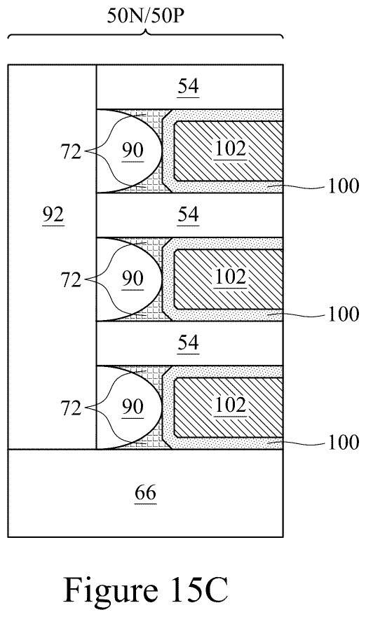

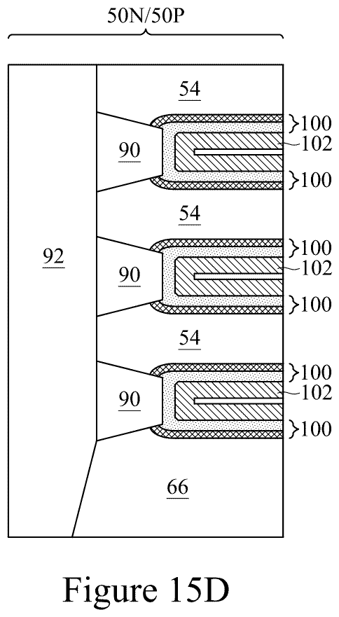

The shape of the inner sidewalls of the inner spacers 90 can be controlled by the choice of etching process used on the sacrificial material 72 in the steps illustrated in FIGS. 9A and 9B. In some embodiments, a normal reactive chemical plasma (RCP) process applied to structure results in rounded sidewalls of the sacrificial material 72. This, in turn, leads to the formation of inner spacers 90 with rounded inner sidewalls, as illustrated in FIG. 10B and 15C. Conversely, a low selective RCP process can be employed to create more squared sidewalls of the sacrificial material 72, which subsequently results in inner spacers 90 with flat inner sidewalls, as shown in FIG. 10C and 15D. The choice between these etching processes allows for precise control over the shape of the inner spacers 90, which can impact the device's electrical characteristics and performance. For instance, rounded inner spacers may provide benefits in terms of stress distribution, while flat inner spacers might offer advantages in terms of more precise control over the spacing between the channel regions and the source/drain regions.

In FIGS. 11A-11E, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as Si, SiP, SiAs, SiP+SiAs/SiSb, SiSb, SiP+SiAs+SiSb, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as SiGe, Ge, GeSn, SiB, SiGe: B, SiGe: Ga, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

FIG. 11C illustrates a plan view of a second nanostructure 54 and epitaxial source/drain regions 92 in accordance with some embodiments. As illustrated in FIG. 11C, the interface between the second nanostructure 54 and the epitaxial source/drain regions 92 is flat or smooth, which is desirable for better junction uniformity and device performance.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11D. In other embodiments, adjacent epitaxial source/drain regions 92 remain separated after the epitaxy process is completed as illustrated by FIG. 11E. In the embodiments illustrated in FIGS. 11D and 11E, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

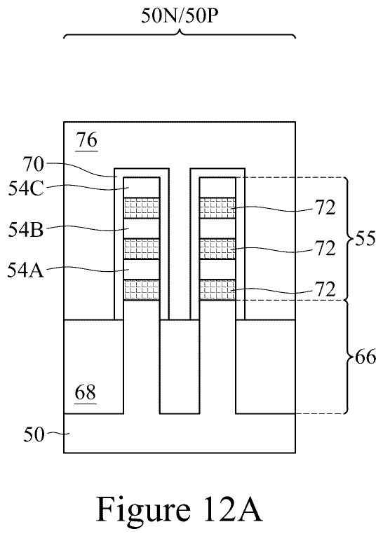

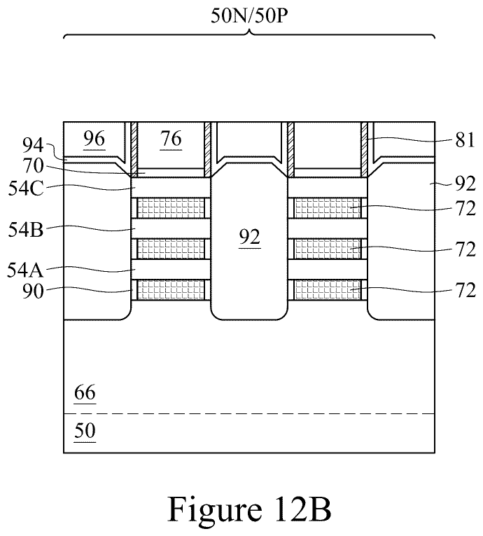

In FIGS. 12A and 12B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

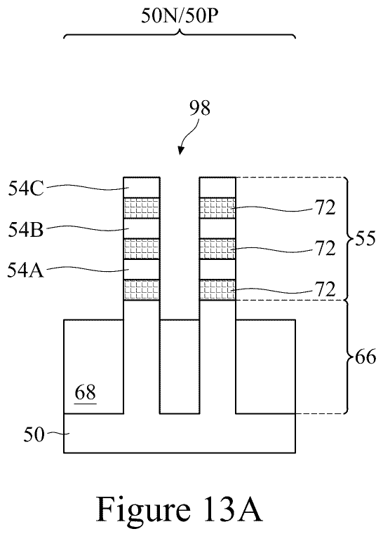

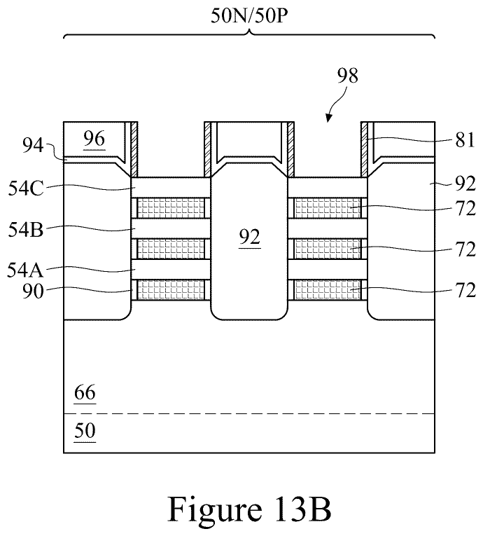

In FIGS. 13A and 13B, the dummy gates 76, and the masks 78 if present, are removed in one or more etching steps, so that second recesses 98 are formed. Portions of the dummy gate dielectrics 70 and portions of the protective liner 118 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

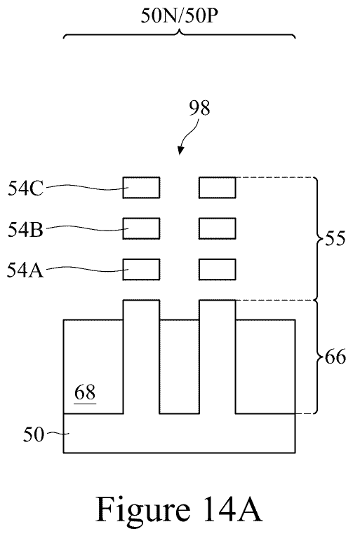

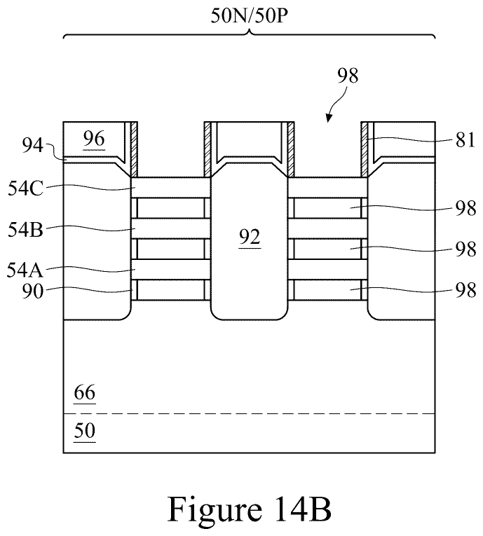

In FIGS. 14A and 14B, the sacrificial material 72 is removed, which extends the second recesses 98. The removal of the sacrificial material 72 may involve an isotropic etching process, such as a wet etching using dilute hydrofluoric acid (HF) or a chemical oxide removal (COR) dry etch. These etchants are selective to the materials of the sacrificial material 72, ensuring that the second nanostructures 54 remain relatively unetched in comparison to the sacrificial material 72. The sacrificial material 72 may be completely removed, or a residue of the sacrificial material 72 may remain on sidewalls of the inner spacers in the second recesses 98 (see e.g., FIG. 15C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not shown) at a top surface to protect the underlying STI regions 68 from etching while patterning and removing the sacrificial material 72. In such embodiments, the hard mask may comprise, for example, a nitride.

In FIGS. 15A-15D, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 15A-15C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

In some embodiments, each of the second semiconductor nanostructures 54 may have a substantially uniform thickness as viewed in the cross-sectional view of FIG. 15B. For example, the second semiconductor nanostructures 54 may have a thickness T3 at the edge over the inner spacers 90 and may have a thickness T4 near the center of the second semiconductor nanostructures 54. In some embodiments, the thickness T3 and T4 are substantially equal.

Reducing germanium impurity residue can improve device performance by maintaining the intended stress profile in the channel regions and minimizing undesired diffusion effects. These significantly reduced germanium residue levels are achieved through the use of the DOI process described herein. The reduction in germanium residue can alter the stress on NFET/PFET devices, potentially leading to improved hole mobility in PFET devices and modified electron mobility in NFET devices. FIG. 15B illustrates a region 103 (sometimes referred to as an end or “tiger tooth” e.g., the interface between the channel region and the source/drain region) of the second semiconductor nanostructures where the disclosed embodiments result in less chance of germanium impurity remaining in the regions 103 and the inner spacers 90 after the formation of the epitaxial source/drain regions 92. The region 103 may be an end of the second semiconductor structure near the epitaxial source/drain regions 92 and an edge or corner of the gate structure. In some embodiments, the region 103 of the second semiconductor structure 54 has a germanium concentration is in a range from 10⁻² to 10⁻³ percent. (e.g., less than 0.003%). Further, in the disclosed embodiments, the inner spacers 90 have a germanium concentration in a range from 10⁻² to 10⁻³ percent. (e.g., less than 0.003%). In related processes, the germanium concentration is higher in the semiconductor structures and in the inner spacers. Thus, the disclosed embodiments significantly reduce the germanium residue remaining in the second semiconductor nanostructures 54 and the inner spacers 90. This can improve the yield and performance of the resulting device.

The manufacturing method used to produce the semiconductor device described herein can be identified through analysis of the germanium impurity residue levels. This analysis technique provides a way to distinguish between devices manufactured using the related SiGe process and those manufactured using the Disposable Oxide Interposer (DOI) process of the present disclosure. In particular, the significantly lower germanium impurity levels in the channel regions and inner spacers, as described above, serve as a fingerprint of the DOI process. Energy-dispersive X-ray spectroscopy (EDX) or similar analytical techniques can be employed to measure the germanium concentration at various locations in the device structure, such as at the “tiger teeth” positions and within the inner spacers. The presence of germanium impurity levels in the range of 10⁻² to 10⁻³ percent at these locations is indicative of the DOI process, while higher levels suggest the use of a related SiGe process. This analysis method not only confirms the efficacy of the DOI process in reducing germanium impurity but also provides a means to verify the manufacturing process used in device production.

FIG. 15C illustrates a detailed view of various elements of FIG. 15B, including the epitaxial source/drain regions 92, the gate dielectric layers 100, the gate electrodes 102, the second nanostructures 54, and the inner spacers 90. In some embodiments, illustrated by FIG. 15C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

In FIG. 15C, the inner spaces 90 have a rounded interface with gate structures 100/102 and the residue of the sacrificial material 72. FIG. 15D illustrates a detailed view of various elements of FIG. 15B in accordance with some embodiments. In FIG. 15D, the inner spaces 90 have a squared or flat interface with gate structures 100/102. Also illustrated in FIGS. 15C and 15D, the height of the inner spacers 90 can taper or get smaller when moving from the epitaxial source/drain regions 92 towards the gate structure 100/102. FIG. 15D further illustrates that the gate dielectric layer 100 comprises multiple layers (e.g., an oxide layer and a high-k layer), and that the gate electrode 102 comprises multiple layers (e.g., liner layers, work function tuning layers, and a fill material).

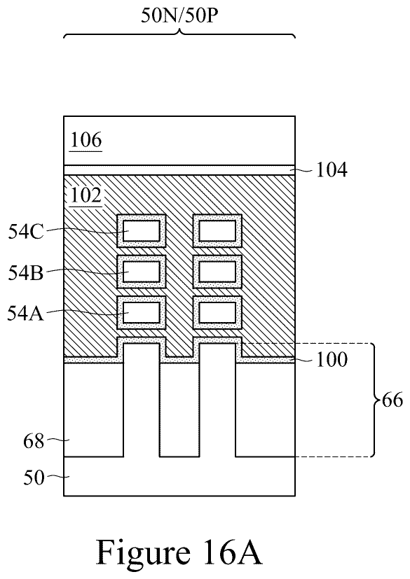

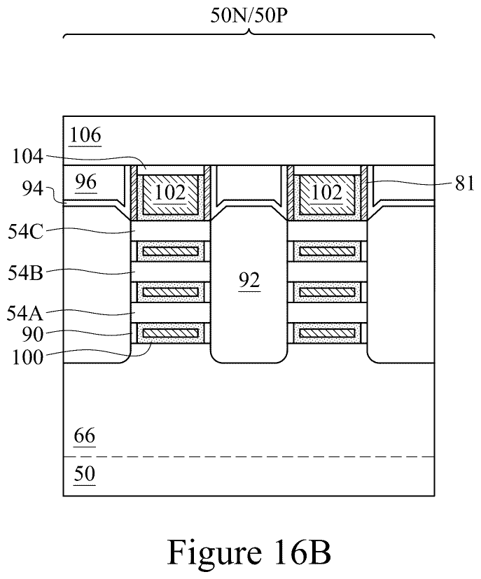

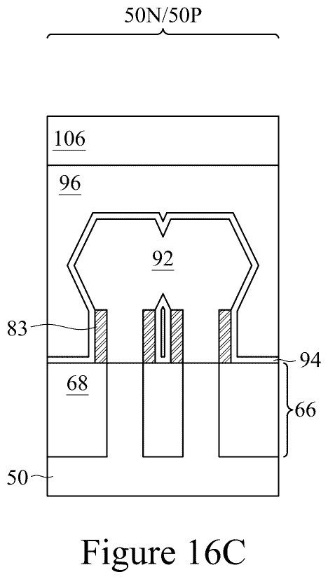

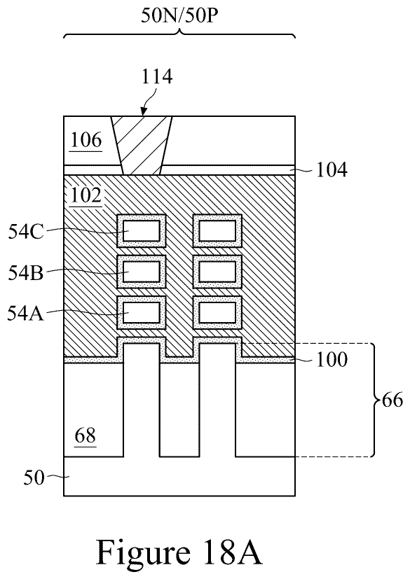

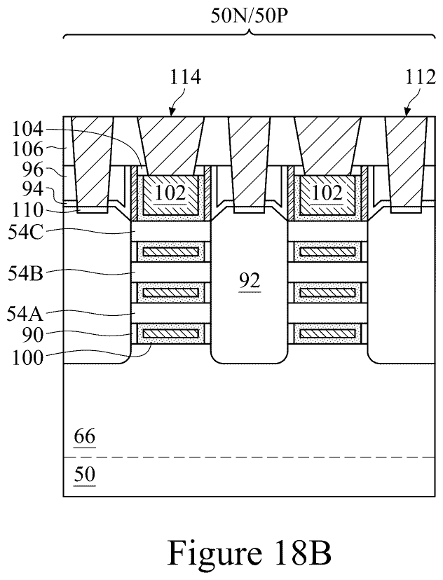

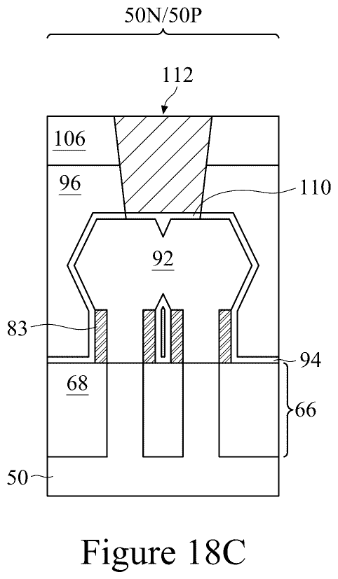

In FIGS. 16A-16C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 18A-18C) penetrate through the gate mask 104 to contact the top surface of the recessed gate electrodes 102.

As further illustrated by FIGS. 16A-16C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

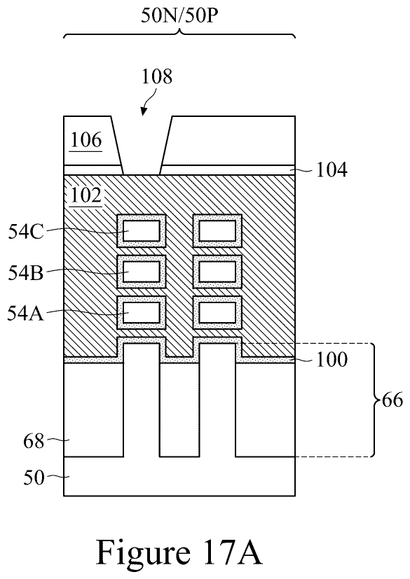

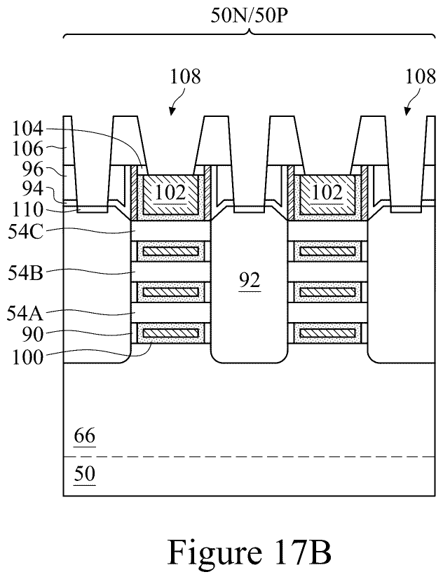

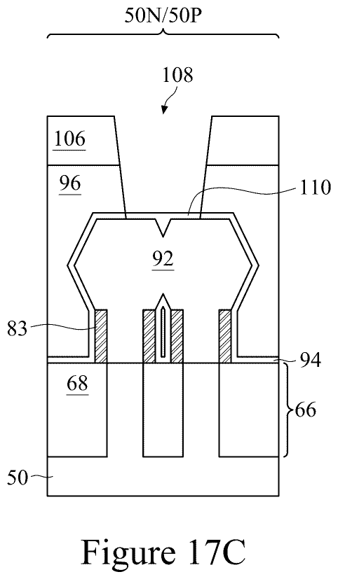

In FIGS. 17A-17C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 18B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 18A-18C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts 114, and the contacts 112 are electrically coupled to the silicide regions 110 and may be referred to as source/drain contacts 112. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

The embodiments disclosed herein provide several advantages in the fabrication of nano-FETs. The DOI process allows for improved control over the device structure and composition, resulting in enhanced device performance.

One advantage of the disclosed embodiments is the substantial reduction of germanium (Ge) impurity concentration in the final device structure. By removing the silicon-germanium (SiGe) sacrificial layers earlier in the fabrication process, the diffusion of Ge through source/drain (SD) regions and interlayer dielectric (ILD) during subsequent thermal steps is minimized. The resulting Ge concentration in the semiconductor layers and inner spacers is typically in the range of 10⁻² to 10⁻³ percent (e.g., less than 0.003%). This reduction in Ge impurity can lead to improved carrier mobility in both NFET and PFET devices, potentially boosting overall device performance.

The DOI process also offers greater flexibility in device design. It enables the production of thinner nanostructures, which can improve electrostatic control in the channel region. The process allows for the formation of inner spacers with varying geometries—either squared (flat) or rounded—and typically results in thicker inner spacers compared to related processes. This flexibility in inner spacer design provides better isolation between the gate and source/drain regions, which can be tailored to specific device requirements.

Furthermore, the disclosed embodiments can result in a larger gate structure, potentially reducing gate resistance. The interface between the inner spacer and the gate structure can be engineered to be either squared or rounded, offering another parameter for device optimization. These structural characteristics can be fine-tuned through process variations, allowing for the creation of nano-FET structures tailored to specific performance requirements.

The DOI process also provides improved control over the etching steps, allowing for more precise shaping of the nanostructures. This precision can lead to more consistent device performance across a wafer and from wafer to wafer, potentially improving manufacturing yield.

In summary, the disclosed embodiments offer a method for nano-FET fabrication that provides better control over impurities, enhanced flexibility in device design, and the potential for improved device performance. These advantages make the DOI process a valuable approach for the continued scaling and improvement of semiconductor devices.

In an embodiment, a method may include forming a multi-layer stack over a substrate, the multi-layer stack having alternating layers of first semiconductor layers and second semiconductor layers. The method may also include removing the first semiconductor layers. Furthermore, the method may include forming a disposable material between the second semiconductor layers. In addition, the method may include forming source/drain regions adjacent to the second semiconductor layers and the disposable material. Moreover, the method may include replacing the disposable material with a metal gate structure, where a germanium concentration in the second semiconductor layers after replacing the disposable material with the metal gate structure is in a range from 10⁻² to 10⁻³ percent.

The described embodiments may also include one or more of the following features. The method where the disposable material may include silicon oxide, silicon oxynitride, silicon nitride, silicon oxycarbonitride, hafnium oxide, or aluminum oxide. The method may include performing an implantation process to introduce dopants into the source/drain regions after forming the disposable material between the second semiconductor layers. The method where replacing the disposable material with the metal gate structure further may include removing the disposable material using an etching process that is selective to the disposable material over the second semiconductor layers. The method may include forming inner spacers on sidewalls of the disposable material. The method where the inner spacers may include silicon nitride, silicon oxynitride, or a combination thereof. The method where the inner spacers have a convex shape, a concave shape, or a flat shape facing the disposable material. The method where a germanium concentration in the inner spacers is in a range from 10-2 to 10-3 percent. The method where forming the inner spacers may include etching the disposable material using a reactive chemical plasma process to form recesses and depositing an inner spacer material in the recesses. The method where the first semiconductor layers may include silicon germanium and the second semiconductor layers may include silicon. The method may include forming dummy gates over the multi-layer stack prior to removing the first semiconductor layers and removing the dummy gates prior to replacing the disposable material with the metal gate structure.

In an embodiment, a method may include forming a multi-layer stack over a substrate, the multi-layer stack having alternating layers of first semiconductor layers and second semiconductor layers. The method may also include patterning the multi-layer stack to define a fin. Furthermore, the method may include forming a first recess adjacent to the fin. In addition, the method may include selectively removing the first semiconductor layers. Moreover, the method may include forming a sacrificial material between the second semiconductor layers. The method may also include growing an epitaxial source/drain region in the first recess adjacent to the second semiconductor layers. Furthermore, the method may include replacing the sacrificial material with a metal gate structure, where a germanium concentration in the second semiconductor layers after replacing the sacrificial material with the metal gate structure is less than 0.01 percent.

The described embodiments may also include one or more of the following features. The method where the sacrificial material may include silicon oxide, silicon oxynitride, silicon nitride, silicon oxycarbonitride, hafnium oxide, or aluminum oxide. The method may include forming inner spacers on sidewalls of the sacrificial material where the inner spacers have a convex shape, a concave shape, or a flat shape facing the sacrificial material. The method where forming the inner spacers may include etching the sacrificial material using a reactive chemical plasma (RCP) process to form second recesses where the RCP process is selected from a normal RCP process resulting in rounded recesses for rounded inner spacers and a low selective RCP process resulting in squared recesses for flat inner spacers and depositing an inner spacer material in the second recesses. The method may include forming inner spacers on sidewalls of the sacrificial material prior to growing the epitaxial source/drain region where an interface between the inner spacers and the metal gate structure has a substantially flat profile. The method where the second semiconductor layers have a substantially uniform thickness throughout the metal gate structure. The method may include forming dummy gates over the multi-layer stack prior to selectively removing the first semiconductor layers and removing the dummy gates prior to replacing the sacrificial material with the metal gate structure.

In an embodiment, a semiconductor device may include a plurality of nanostructure channel layers stacked over a substrate, where each of the nanostructure channel layers has a germanium concentration of less than 0.01 percent. The semiconductor device may also include source/drain regions adjacent to the nanostructure channel layers. Furthermore, the device may include inner spacers disposed between the nanostructure channel layers and adjacent to the source/drain regions, where the inner spacers have a germanium concentration of less than 0.01 percent. In addition, the device may include a gate structure wrapping around each of the nanostructure channel layers, where an interface between the inner spacers and the gate structure has a substantially flat profile.

The described embodiments may also include one or more of the following features. The semiconductor device where each of the nanostructure channel layers has a substantially uniform thickness throughout the gate structure, and the gate structure may include a gate dielectric layer conformally covering surfaces of the nanostructure channel layers and a metal gate electrode layer disposed on the gate dielectric layer, where the metal gate electrode layer fills spaces between adjacent nanostructure channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a multi-layer stack over a substrate, the multi-layer stack comprising alternating layers of first semiconductor layers and second semiconductor layers;
removing the first semiconductor layers;
forming a disposable material between the second semiconductor layers;
forming source/drain regions adjacent the second semiconductor layers and the disposable material; and
replacing the disposable material with a metal gate structure, wherein a germanium concentration in the second semiconductor layers after replacing the disposable material with the metal gate structure is in a range from 10⁻² to 10⁻³ percent.

2. The method of claim 1, wherein the disposable material comprises silicon oxide, silicon oxynitride, silicon nitride, silicon oxycarbonitride, hafnium oxide, or aluminum oxide.

3. The method of claim 1, further comprising:
performing an implantation process to introduce dopants into the source/drain regions after forming the disposable material between the second semiconductor layers.

4. The method of claim 1, wherein replacing the disposable material with the metal gate structure further comprises:
removing the disposable material using an etching process that is selective to the disposable material over the second semiconductor layers.

5. The method of claim 1, further comprising:
forming inner spacers on sidewalls of the disposable material.

6. The method of claim 5, wherein the inner spacers comprise silicon nitride, silicon oxynitride, or a combination thereof.

7. The method of claim 5, wherein the inner spacers have a convex shape, a concave shape, or a flat shape facing the disposable material.

8. The method of claim 5, wherein a germanium concentration in the inner spacers is in a range from 10⁻² to 10⁻³ percent.

9. The method of claim 5, wherein forming the inner spacers comprises:
etching the disposable material using a reactive chemical plasma process to form recesses; and
depositing an inner spacer material in the recesses.

10. The method of claim 1, wherein the first semiconductor layers comprise silicon germanium and the second semiconductor layers comprise silicon.

11. The method of claim 1, further comprising:
forming dummy gates over the multi-layer stack prior to removing the first semiconductor layers; and
removing the dummy gates prior to replacing the disposable material with the metal gate structure.

12. A method, comprising:
forming a multi-layer stack over a substrate, the multi-layer stack comprising alternating layers of first semiconductor layers and second semiconductor layers;
patterning the multi-layer stack to define a fin;
forming a first recess adjacent to the fin;
selectively removing the first semiconductor layers;
forming a sacrificial material between the second semiconductor layers;
growing an epitaxial source/drain region in the first recess adjacent to the second semiconductor layers; and
replacing the sacrificial material with a metal gate structure, wherein a germanium concentration in the second semiconductor layers after replacing the sacrificial material with the metal gate structure is less than 0.01 percent.

13. The method of claim 12, wherein the sacrificial material comprises silicon oxide, silicon oxynitride, silicon nitride, silicon oxycarbonitride, hafnium oxide, or aluminum oxide.

14. The method of claim 12, further comprising:
forming inner spacers on sidewalls of the sacrificial material, wherein the inner spacers have a convex shape, a concave shape, or a flat shape facing the sacrificial material.

15. The method of claim 14, wherein forming the inner spacers comprises:
etching the sacrificial material using a reactive chemical plasma (RCP) process to form second recesses, wherein the RCP process is selected from a normal RCP process resulting in rounded recesses for rounded inner spacers and a low selective RCP process resulting in squared recesses for flat inner spacers; and
depositing an inner spacer material in the second recesses.

16. The method of claim 12, further comprising:
forming inner spacers on sidewalls of the sacrificial material prior to growing the epitaxial source/drain region, wherein an interface between the inner spacers and the metal gate structure has a substantially flat profile.

17. The method of claim 12, wherein the second semiconductor layers have a substantially uniform thickness throughout the metal gate structure.

18. The method of claim 12, further comprising:
forming dummy gates over the multi-layer stack prior to selectively removing the first semiconductor layers; and
removing the dummy gates prior to replacing the sacrificial material with the metal gate structure.

19. A semiconductor device, comprising:
a plurality of nanostructure channel layers stacked over a substrate, wherein each of the nanostructure channel layers has a germanium concentration of less than 0.01 percent;
source/drain regions adjacent to the nanostructure channel layers;
inner spacers disposed between the nanostructure channel layers and adjacent to the source/drain regions, wherein the inner spacers have a germanium concentration of less than 0.01 percent; and
a gate structure wrapping around each of the nanostructure channel layers, wherein an interface between the inner spacers and the gate structure has a substantially flat profile.

20. The semiconductor device of claim 19, wherein:
each of the nanostructure channel layers has a substantially uniform thickness throughout the gate structure; and
the gate structure comprises:
a gate dielectric layer conformally covering surfaces of the nanostructure channel layers; and
a metal gate electrode layer disposed on the gate dielectric layer, wherein the metal gate electrode layer fills spaces between adjacent nanostructure channel layers.
